(19) United States
(12) Patent Application Publication
(10) Pub. No.: US 2012/0327709 A1
(43) Pub. Date: Dec. 27, 2012

(54) PROGRAMMING OF PHASE-CHANGE MEMORY CELLS

(75) Inventors: Urs Frey, Zurich (CH); Angeliki Pantazi, Zurich (CH); Nikolaos Papandreou, Zurich (CH); Charalampos Pozidis, Zurich (CH); Abu Sebastian, Zurich (CH)

(73) Assignee: International Business Machines Corporation, Armonk, NY (US)

(21) Appl. No.: 13/597,601

(22) Filed: Aug. 29, 2012

Related U.S. Application Data
(63) Continuation of application No. 13/415,061, filed on Mar. 8, 2012.

(30) Foreign Application Priority Data
Mar. 10, 2011 (EP) 11157709.4

(51) Int. Cl. G11C 11/00

(52) U.S. Cl. 365/163; 365/148

(57) ABSTRACT

A method and apparatus for programming a phase-change memory cell. A bias voltage signal (V_{BL}) is applied to the cell. A measurement portion (m) of this bias voltage signal has a profile which varies with time. A measurement (T_{M}), which is dependent on a predetermined condition being satisfied, is then made. The predetermined condition is dependent on cell current during the measurement portion (m) of the bias voltage signal. A programming signal is generated in dependence on the measurement (T_{M}), and the programming signal is applied to program the cell.

### CROSS-REFERENCE TO RELATED APPLICATION

This application is a continuation of and claims priority from U.S. application Ser. No. 13/415,061 filed on Mar. 8, 2012, which in turn claims priority under 35 U.S.C. §119 from European Patent Application No. 11157709.4 filed Mar. 10, 2011. Furthermore, this application is also related to commonly owned U.S. patent application Ser. No. 13/415,012 and commonly owned U.S. patent application Ser. No. 13,415,127 both of which were filed concurrent with Ser. No. 13/415,061 on Mar. 8, 2012. The entire contents of all of the aforementioned applications are incorporated herein by reference.

### BACKGROUND OF THE INVENTION

1. Field of the Invention

This invention relates generally to phase-change memory and, more particularly, to methods and apparatuses for programming phase-change memory cells.

2. Description of Related Art

Phase-change memory (PCM) is a new, non-volatile solid-state memory technology which exploits the reversible switching of certain chalcogenide materials between at least two states with different electrical conductivity. PCM is fast, has good retention and endurance properties and has been shown to scale to the future lithography nodes.

In single-level cell (SLC) PCM devices, the fundamental storage unit (the “cell”) can store one bit of binary information. The cell can be set to one of two states, crystalline and amorphous, by application of heat. In the amorphous state, which represents binary 0, the electrical resistance of the cell is high. When heated to a temperature above its crystallization point and then cooled, the chalcogenide material is transformed into an electrically-conductive, crystalline state. This low-resistance state represents binary 1. If the cell is then heated to a high temperature, above the chalcogenide melting point, the chalcogenide material reverts back to its amorphous state on rapid cooling.

In multilevel-cell (MLC) PCM devices, a memory cell can be set to s different states, where s>2, permitting storage of more than one bit per cell. MLC operation is achieved by exploiting partially-amorphous states of the PCM cell. Different cell states are set by varying the size of the amorphous region within the chalcogenide material. This varies cell resistance. Thus, each cell state corresponds to a different amorphous volume which corresponds to a different resistance level.

Data is written to a PCM cell by programming the cell so as to set the cell-state to the desired level. To program a PCM cell, a voltage or current pulse is applied to the cell to heat the chalcogenide material to an appropriate temperature to induce the desired cell-state on cooling. By varying the amplitude of the voltage or current pulses, different cell-states can be achieved. Reading of PCM cells is performed using cell resistance as a metric for cell-state. The resistance of a cell can be measured in various ways, usually by biasing the cell at a certain constant voltage level and measuring the current that flows through it. U.S. Pat. No. 7,505,334 B1 discloses an alternative method whereby cell resistance is detected from the discharge time of an RC (resistor-capacitor) circuit in which the cell is the resistor. However measured, the resulting resistance indicates cell-state according to the predefined correspondence between resistance levels and cell-states.

The resistance measurement for a read operation is performed in the sub-threshold region of the current-versus-voltage (I/V) characteristic of the cell, i.e. in the region below the threshold switching voltage at which a change in cell-state can occur. Since the threshold switching occurs at a fixed electric field, the states which correspond to low amorphous size undergo threshold switching at lower bias voltages. A low, and hence safe, bias voltage is used for reading all cells. In this low-field region, all cells can be read without affecting cell-state.

Programming in PCM technology is done either by application of a single pulse or by using a sequence of pulses in a procedure known as iterative programming, or iterative write. When programming with a single pulse, the cell is typically read after programming to verify that the desired state has been achieved. This is done because lack of knowledge of the programming characteristics of each cell and inherent inter-cell variability can adversely affect write accuracy. In an iterative write procedure, a sequence of programming pulses is employed. Each programming pulse is followed by a read-verification step, and the cell-state achieved is compared with the desired cell-state. The difference is then used to determine the pulse amplitude for the next programming pulse, and so on. In this way the programmed state gradually converges on the desired cell-state.

### SUMMARY OF THE INVENTION

One embodiment of an aspect of the present invention provides a method for programming a phase-change memory cell. The method includes applying a bias voltage signal (V_{BL}) to the cell, a measurement portion (m) of the bias voltage signal having a profile which varies with time, making a measurement (T_{M}) dependent on a predetermined condition, which condition is dependent on cell current during the measurement portion of the bias voltage signal, being satisfied, generating a programming signal in dependence on said measurement (T_{M}), and applying the programming signal to program the cell.

In a second embodiment an apparatus for programming a phase-change memory cell is described. The apparatus includes a signal generator for generating a bias voltage signal (V_{BL}) to be applied to the cell, a measurement portion (m) of the bias voltage signal having a profile which varies with time, a measurement circuit for making a measurement (T_{M}) dependent on a predetermined condition, which condition is dependent on cell current during the measurement portion (m) of the bias voltage signal, being satisfied, and a programming circuit for generating a programming signal in dependence on the measurement (T_{M}) and applying the programming signal to program the cell.

In a third embodiment, a phase-change memory device is provided. The phase-change memory device includes a memory comprising a plurality of phase-change memory cells, and a read/write apparatus for reading and writing data in the phase-change memory cells, wherein the read/write apparatus includes an apparatus for programming a memory cell, the apparatus including a signal generator for generating a bias voltage signal (V_{BL}) to be applied to the cell, a measurement portion (m) of the bias voltage signal having a profile which varies with time, a measurement circuit for making a measurement (T_{M}) dependent on a predetermined condition, which condition is dependent on cell current during the measurement portion (m) of the bias voltage signal, being satisfied and a programming circuit for generating a programming signal in dependence on the measurement (T_{M}) and applying the programming signal to program the cell.

### BRIEF DESCRIPTION OF THE DRAWINGS

Preferred embodiments of the invention will now be described with reference to the accompanying drawings:

FIG. 1 illustrates simulated I/V characteristics for different resistance levels of a PCM cell;

FIG. 2 is a schematic block diagram of a phase-change memory device embodying the invention;

FIG. 3 is a schematic illustration of a PCM cell;

FIG. 4 illustrates voltage and current signals in an iterative programming operation performed by the FIG. 2 device;

FIG. 5 is a schematic block diagram of programming apparatus of the FIG. 2 device for performing the iterative programming operation;

FIG. 6 illustrates various signals used in operation of the programming apparatus;

FIG. 7 illustrates convergence of programmed cell-state during an iterative programming operation;

FIG. 8 illustrates a current thresholding technique used in a measurement operation performed by the programming apparatus to obtain a time metric for cell-state;

FIG. 9 compares cell programming curves obtained with the time metric and the conventional low-field resistance metric;

FIG. 10 shows the time metric as a function of amorphous thickness;

FIG. 11 shows another embodiment of programming apparatus for the FIG. 2 device;

FIG. 12 illustrates various signals used in operation of the FIG. 11 apparatus;

FIG. 13 shows a further embodiment of programming apparatus for performing single-pulse programming in the FIG. 2 device;

FIGS. 14a and 14b illustrate a different technique for generating a time metric in embodiments of the invention;

FIG. 15 illustrates a modification to the time metric generation technique of FIG. 4;

FIGS. 16a and 16b illustrate other possible modifications to the time metric generation technique; and

FIG. 17 illustrates a further technique for generating a time metric in embodiments of the invention.

### DETAILED DESCRIPTION OF THE PREFERRED EMBODIMENTS

In programming methods embodying this invention, a measurement portion of the bias voltage signal applied to the cell has a profile which varies with time. During application of this time-varying signal portion, a measurement is made. This measurement is dependent on a predetermined condition, which depends on the current flowing through the cell, being satisfied. For example, in some embodiments the measurement is indicative of the bias voltage level at which the current-dependent condition is satisfied.

In other embodiments the measurement is indicative of the time taken for the current-dependent condition to be satisfied. In any case, the resulting measurement can then be used as a metric for cell-state and programming can be performed in dependence on this measurement. As the bias voltage varies during the measurement portion in methods embodying the invention, the cell current varies accordingly in dependence on the I/V characteristic for the cell state in question. By obtaining a measurement which is dependent on the cell current satisfying a predetermined condition, the measurement operation can exploit differences in form of the I/V characteristic for different cell states in a effective manner.

The resulting measurement provides a good metric for amorphous size (the fundamental programmed entity) and hence for cell-state. The programming signal for the cell can then be generated in dependence on this measurement. Thus, information on current cell-state can be obtained via the measurement operation and can be used to determine the appropriate signal for the programming operation. This technique can provide the basis for efficient programming operations, offering significant improvements in programming accuracy and bandwidth.

The measurement can provide a priori information on cell characteristics which can allow more accurate programming. As explained in detail below, the measurement can provide a good metric for cell-state. Embodiments of the invention can allow accurate single-pulse programming, reducing the need for a subsequent read-verification step. Further embodiments can allow faster iterative programming operations. Particularly preferred embodiments can offer efficient operation by exploiting part of the signal pulses employed in a programming operation to obtain the measurement for that operation. In addition, methods embodying the invention can be implemented via analog circuitry, avoiding the need for elaborate digital logic circuits.

In embodiments of the invention, the measurement operation and the application of the programming signal based on this measurement are performed within a single pulse of the bias voltage signal. In particular, in methods according to embodiments of the invention the bias voltage signal comprises a bias voltage pulse and the measurement portion of the bias voltage signal comprises a leading portion of the bias voltage pulse.

The programming signal is then applied during a subsequent portion of the bias voltage pulse. In this way, information on cell state obtained during the leading portion, i.e. at or towards the beginning, of the bias voltage pulse can be used to program the cell subsequently within the same pulse. The measurement and programming operations can be thus performed within a single programming cycle, providing high efficiency. The bandwidth improvement offered by methods embodying this invention can be especially useful in iterative programming procedures where multiple pulses are required to perform each single write operation.

While it can be preferable to use the leading portion of the bias voltage pulse for the measurement operation, alternatives can be envisaged, e.g. using a measurement made during the trailing portion of one pulse in an iterative procedure to determine the programming signal used during the next pulse.

In some embodiments the profile of the measurement portion of the bias voltage signal is predetermined. In particular, the measurement portion can have a predetermined profile which varies with time over a range of voltage levels. With such a predetermined measurement portion, the measurement that is made can be indicative of the time taken for the predetermined condition to be satisfied. This provides a time-based metric for determining cell-state. Embodiments can be envisaged, however, in which the profile of the measurement portion does not vary with time in a predetermined manner. In these embodiments, the measurement that is made can be indicative of the bias voltage level at which the predetermined condition is satisfied. As an example, the bias voltage level can be varied in a substantially random manner during the measurement portion until the current-dependent condition is determined to be satisfied, the bias voltage level at which this occurs being measured in this case. This will be discussed further below.

In general, the profile of the measurement portion of the bias voltage signal can vary in an analog or a digital manner. In embodiments where this profile is predetermined, the predetermined profile preferably increases with time over the range of voltage levels. In particular, it is preferred here that the profile generally increases with increasing time and, according to a particular embodiment, increases monotonically with time. Particularly preferred methods make the cell-state measurement on the rising edge of a bias voltage pulse, performing programming during the remainder of the pulse. The profile can be a linear function of time, or a non-linear function of time, and examples of both cases will be discussed below.

The programming signal can be implemented as a separate signal to the bias voltage signal or can form part of the bias voltage signal itself. In particular, some methods embodying the invention can generate the programming signal by modifying the bias voltage signal. The programming signal is then applied as the modified bias voltage signal. For example, where the cell-state measurement is made during a leading portion of a bias voltage signal, the profile of a subsequent portion of the bias voltage signal can be modified to produce the programming signal. The profile can be modified in various ways, for example by varying the amplitude or duration of a signal pulse or even the duration of the trailing edge of the pulse.

Cell programming by means of voltage pulses applied to the cell can be performed by generating the programming signal via modification of the bias voltage signal as just described. In alternative embodiments, where the cell is connected to an access device for controlling cell operation in dependence on a control signal associated with the access device, the programming method can include generating the programming signal by modifying the control signal. While alternatives can be readily envisaged, a transistor is conveniently employed as such an access device, the control signal comprising a control voltage for the transistor, e.g. the gate voltage of a field-effect transistor. Such an access device allows cell current to be controlled. Hence, when the programming signal is generated by modifying the access device control signal, cell programming can be achieved by means of current pulses applied to the cell. Various attributes of the control signal, such as amplitude, duration etc., can be modified to produce the programming signal as before.

The cell-state measurement can be used in various ways in generation of the programming signal. Some methods can include generating the programming signal in dependence on the difference between the measurement and a reference value corresponding to a desired cell-state. Other examples will be given below.

The programming operation can stop after one pass of steps (a) to (d) above to provide a single-pulse programming system. In iterative-write systems, however, the programming operation can include iteratively performing steps (a) to (d) until a predetermined programming criterion is satisfied. Such a criterion can be, for instance, that the measurement corresponds to (e.g. is equal to or within predetermined margin of) a reference value indicative of a desired cell-state, or that a predetermined number of iterations has been performed, or that either one of these events has occurred.

In embodiments employing a time-based metric, the measurement indicative of time can be made in any convenient manner, and can directly or indirectly indicate the time in question. Some embodiments can measure time itself in some manner. Other embodiments can measure some other parameter indicative of time. For example, where the measurement portion of the bias voltage signal is a linear function of time, the voltage level at which the predetermined condition is satisfied can be measured as a time indicator. In embodiments where the profile of the measurement portion is not predetermined and a measurement indicative of bias voltage level is made, this measurement can similarly measure bias voltage per se or any convenient parameter indicative thereof.

The predetermined condition can depend on cell current in a variety of ways. The condition can be that the cell current reaches a predetermined current level (in particular that it equals or traverses a predetermined detection threshold). As another example, where the profile of the measurement portion of the bias signal is predetermined, the condition can be that the cell current changes from a first predetermined current level to a second predetermined current level. A predetermined current level employed in these examples can or can not be a function of the bias voltage. Where such a current level is a function of bias voltage, various functions having increasing and/or decreasing profile portions across the bias voltage range can be employed. Examples of these and other embodiments will be described below.

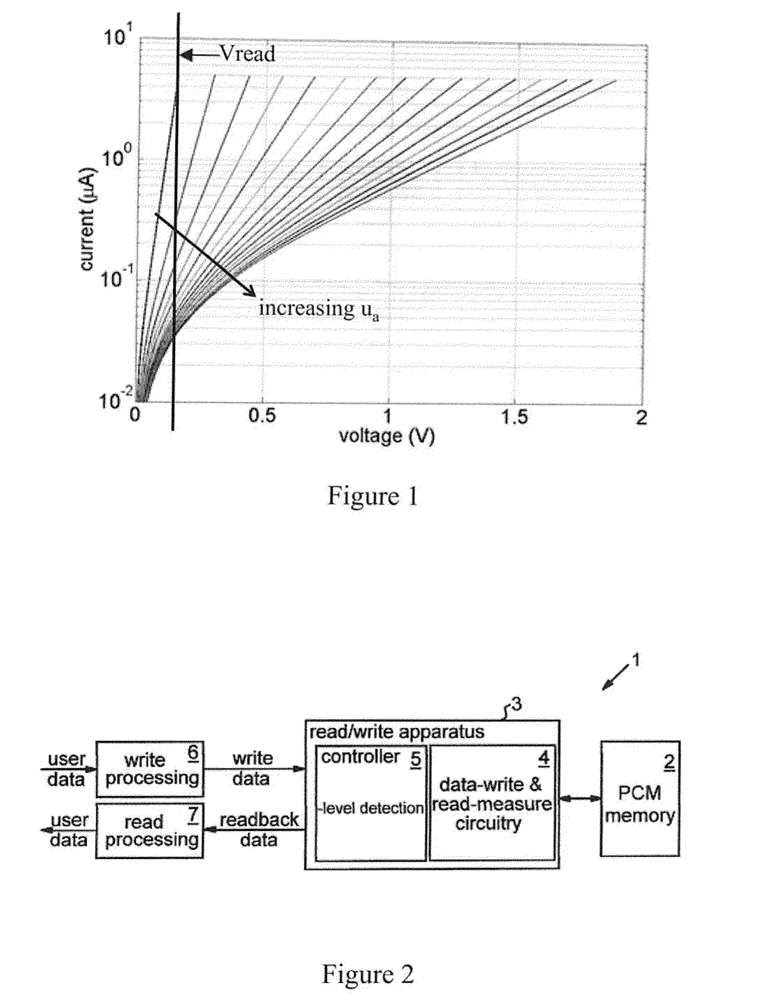

FIG. 1 of the accompanying drawings shows simulated I/V characteristics for sixteen different resistance levels (cell states) based on measurement data obtained from PCM cells. The arrow indicates increasing thickness (uₐ) of the amorphous phase, and the vertical line indicates a typical bias voltage, V_{read}, for measuring low-field resistance on read-back.

The I/V curves of the low-field resistance technique tend to merge at low fields as amorphous thickness increases. In other words, the low-field resistance tends to saturate with increasing amorphous size. This phenomenon, which is due to cell geometry effects, serves to mask increasing size of the amorphous region when using the resistance metric to determine cell state.

FIG. 2 is a simplified schematic of a phase-change memory device embodying the invention. The device 1 includes phase-change memory 2 for storing data in one or more integrated arrays of multilevel PCM cells. Though shown as a single block in the figure, in general memory 2 can include any desired configuration of PCM storage units ranging, for example, from a single chip or die to a plurality of storage banks each containing multiple packages of storage chips. Reading and writing of data to memory 2 is performed by read/write apparatus 3.

Apparatus 3 includes data-write and read-measurement circuitry 4 for programming PCM cells in data write operations and for making cell-state measurements during programming and data read operations as described in detail below. Circuitry 4 can address individual PCM cells for write and read purposes by applying appropriate voltages to an array of word and bit lines in memory ensemble 2. This process can be performed in generally known manner except as detailed hereinafter. A read/write controller 5 controls operation of apparatus 3 generally and includes functionality for determining cell-state, i.e. level detection, based on measurements made by circuitry 4.

The functionality of controller 5 can be implemented in hardware or software or a combination thereof, though use of hardwired logic circuits is generally preferred for reasons of operating speed. Suitable implementations will be apparent to those skilled in the art from the description. As indicated by block 6 in the figure, user data input to device 1 is typically subjected to some form of write-processing, such as coding for error-correction purposes, before being supplied as write data to read/write apparatus 3. Similarly, readback data output by apparatus 3 is generally processed by a read-processing module 7, e.g. performing codeword detection and error correction operations, to recover the original input user data. Such processing by modules 6 and 7 is independent of the cell programming system to be described and need not be discussed in detail here.

When writing data to PCM cells, the apparatus 3 performs an iterative programming procedure in which a series of programming pulses is applied to a cell. During a leading portion of each pulse, a measurement is made which indicates the current state of the cell, and this information is then used to program the cell during a subsequent portion of the programming pulse. The cell-state measurement performed during this process does not rely on the conventional resistance metric of prior systems discussed earlier. Programming techniques embodying this invention are based on an improved metric for the fundamental programmed entity, namely amorphous size, in PCM cells.

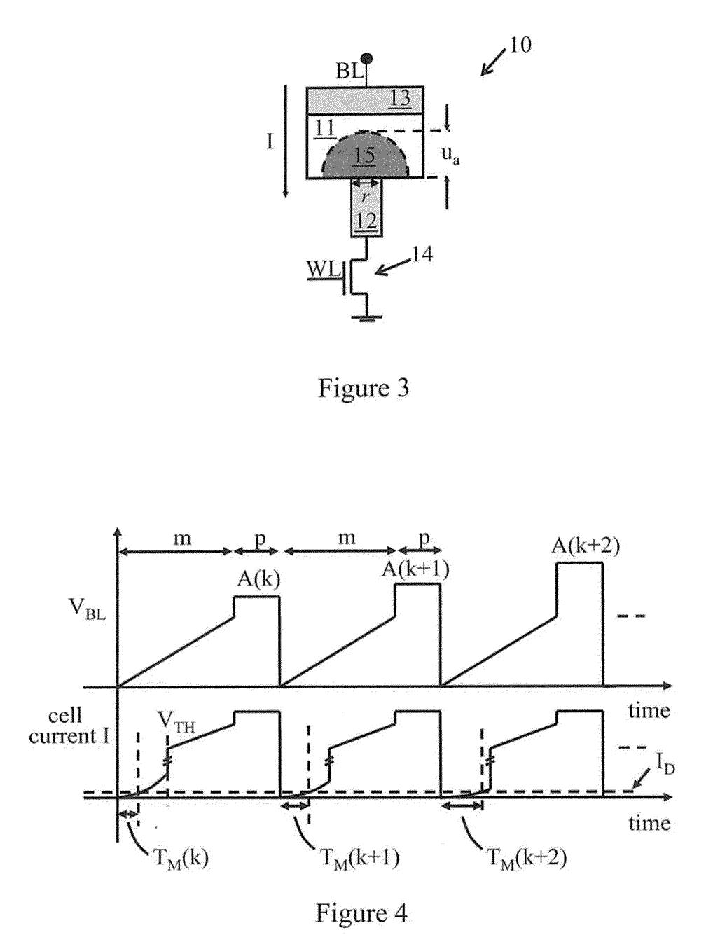

FIG. 3 is a schematic illustration of a typical PCM cell 10. The cell consists of a layer 11 of phase change material, e.g. Germanium Antimony Telluride (GST), sandwiched between a bottom electrode 12 and a top electrode 13. Top electrode 13 is connected to a bit line BL of the memory cell array. The bottom electrode 12 has a radius r of approximately 20 nm and is produced using sub-lithographic means. A transistor 14 is typically used as the access device, the gate contact of this transistor being connected to a word line WL of the array. The amorphous region 15 can be created within the crystalline GST as described earlier by application of a voltage pulse at the bit line BL or the word line WL.

When the pulse is applied at the bit line, the technique is known as voltage-mode programming and the transistor just serves as a selection device. When the pulse is applied at the word line, the technique is known as current-mode programming and the transistor acts as a voltage controlled current source. The size of the resulting amorphous region, indicated in the figure by amorphous thickness uₐ, depends on the amplitude of the programming pulse as already described. The measurement performed during programming in the FIG. 2 device provides a good metric for this amorphous size, and hence for cell-state. The way in which this measurement is obtained and used in a programming operation will first be described with reference to FIGS. 4 to 6.

In the present embodiment, voltage-mode programming is performed via a succession of bias voltage pulses applied to the bit line. The upper trace in FIG. 4 is a schematic illustration of the bias voltage signal V_{BL}. The signal comprises a succession of programming pulses, designated k, k+1, k+2, etc., corresponding to successive cycles of the iterative programming operation. Each pulse consists of a leading measurement portion m and a subsequent programming portion p, the programming portion p being in the form of a signal pulse of variable pulse amplitude A. The measurement portion m of each V_{BL} pulse has a predetermined signal profile which varies with time over a range of voltage levels. In this embodiment, the amplitude profile of the measurement portion m increases monotonically, as a linear function of time, as illustrated schematically in the figure.

During the measurement portion of each V_{BL} pulse, the measurement circuitry 4 of device 1 performs a measurement operation for the cell. This measurement is indicative of the time taken for a predetermined condition, which is dependent on cell current during the measurement portion of the bias voltage signal, to be satisfied. The lower trace in FIG. 4 indicates how cell current I varies with time during application of the bias voltage signal. During each bias voltage pulse, the current initially increases in a non-linear manner. The current increases dramatically when the threshold switching voltage V_{TH} of the cell is reached, and then continues to rise for the remainder of the measurement portion m. The current profile terminates with a pulse corresponding to the programming portion p of the bias voltage signal. During the measurement portion m, the measurement circuitry 4 of this embodiment measures the time taken for the cell current to reach a predetermined current threshold I_{D}.

In this first example, the current threshold I_{D} is set to a constant value which is selected to be less than the threshold switching current I_{TH} for all cell states. The time measurement is therefore completed before the threshold switching voltage V_{TH} is reached. As will be explained in detail below, this measurement provides a good metric for amorphous size and hence for cell-state. The time measurement, or “time metric”, T_{M} obtained for a given V_{BL} pulse is then used to determine the programming pulse amplitude A for that pulse. In particular, in this embodiment the programming pulse amplitude is determined in dependence on the difference between the metric T_{M} and a reference value T_{ref} which corresponds to the desired cell-state after programming:

A(k+1)=A(k)+f(T_{ref}−Tₘ(k+1)).

The function f here can take various forms and in general can be selected as desired for a given system. This function can be implemented, for instance, as a simple gain factor, or by some more complex function, depending on particular requirements of the system in question.

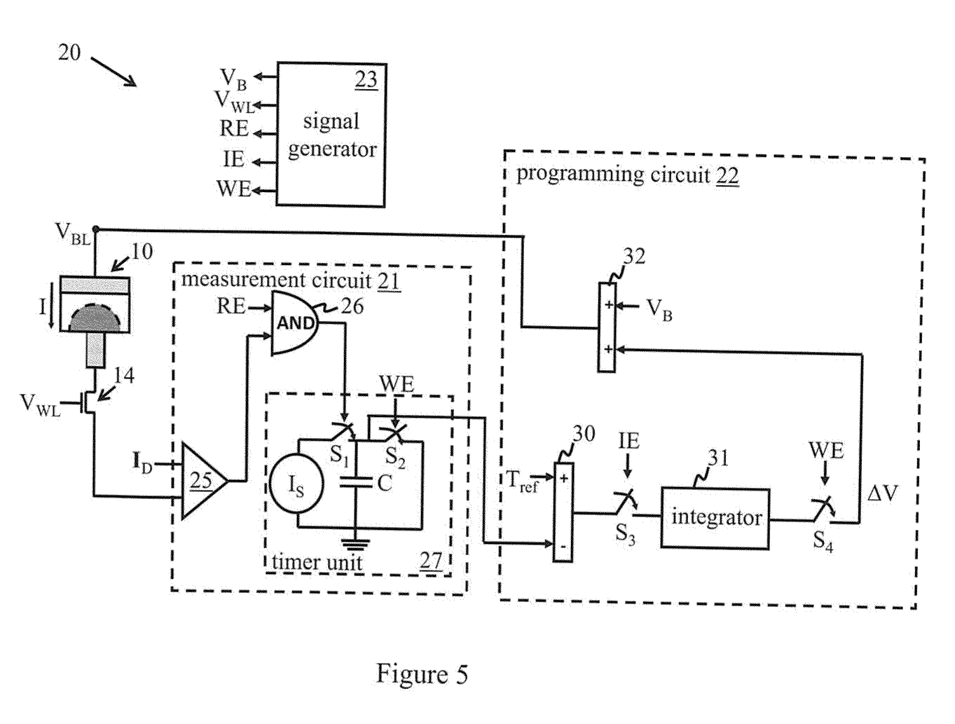

FIG. 5 is a schematic block diagram of programming apparatus, forming part of circuitry 4 in device 1, for implementing the programming method just described. The apparatus 20 has a measurement circuit, indicated generally at 21, and a programming circuit, indicated generally at 22 which are connected as shown to a PCM cell 10 during a programming operation. The apparatus includes a signal generator 23 for generating various signals used in the programming operation. Though represented for simplicity by a single block in the figure, in practice signal generator 23 can be implemented by a plurality of distinct signal generation units.

The measurement circuit 21 includes a comparator 25, an AND gate 26 and a timer unit 27 connected as shown in the figure. Timer unit 27 includes a current source I_{S}, a capacitor C and switches S₁ and S₂ connected as illustrated. The programming circuit includes a difference block 30, an integrator 31, switches S₃ and S₄, and an adder block 32 the output of which is connected to the bit line BL of cell 10. The various circuit components in FIG. 5 can be implemented in any convenient manner, and suitable implementations will be readily apparent to those skilled in the art.

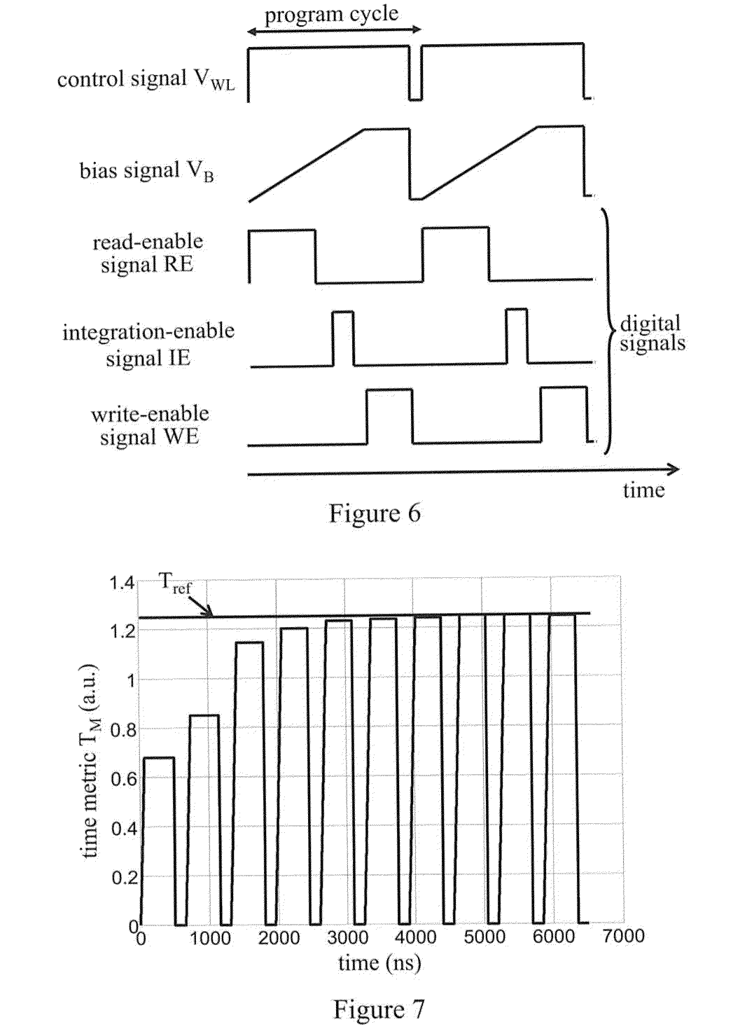

The signals produced by signal generator 23 in operation are illustrated schematically in FIG. 6. These signals include three digital signals for controlling operation of the programming apparatus 20, and two analog signals for controlling operation of cell 10. The digital signals consist of a read-enable signal RE, an integration-enable signal IE and a write-enable signal WE, with the high state representing logic 1 (“ON”) in each case.

The read-enable signal RE defines the time period during which the metric T_{M} is measured. The integration-enable signal defines the time during which a correction signal ΔV is calculated for generating the programming signal. The write-enable signal defines the time during which the programming signal is applied to the cell. The analog signals are the control signal V_{WL} for transistor 14 and a basic bias signal V_{B} which forms one input to adder 32 of apparatus 20, the output of adder 32 constituting the bias voltage signal V_{BL} at the bit line of cell 10.

A programming operation is initiated by controller 5 of device 1 in order to set a cell 10 to a desired state depending on the data to be recorded. In response, signal generator 23 generates the signals shown in FIG. 6 for the first cycle of the iterative programming procedure. Initially, the write-enable signal is OFF, so that switch S₄ is open, and the bias signal V_{B} is applied as the cell bias voltage V_{BL}. This provides the predetermined measurement portion m of the first V_{BL} pulse as shown in FIG. 4. The current I flowing through cell 10 during this period is supplied to one input of comparator 25. Comparator 25 compares the current level I with the predetermined current threshold I_{D} described above. While I<I_{D}, the comparator outputs logic 1 to the corresponding input of AND gate 26.

The other input of AND gate 26 receives the read-enable signal RE. Thus, while RE is ON, the AND gate outputs logic 1 and the switch S₁ of timer unit 27 is closed. While switch S₁ is closed, the capacitor C is charged by current source I_{S}. As soon as cell current rises so that I≧I_{D}, the comparator outputs logic 0 to AND gate 26. The AND gate output then changes to logic 0 and switch S₁ opens. The voltage across capacitor C when switch S₁ opens is thus determined by the time taken for the cell current I to reach the current threshold I_{D}. This voltage provides the time metric T_{M} for the current programming cycle.

The time metric T_{M} from measurement circuit 21 is output to programming circuit 22 and applied at the subtracting input of difference block 30. The additive input to block 30 receives the reference value T_{ref} from controller 5 of device 1. This reference value T_{ref} represents the time metric value corresponding to the desired cell-state to be achieved by the programming operation. When the integration-enable signal IE subsequently goes high, switch S₃ closes and the difference output (T_{ref}−T_{M}) is integrated in integrator block 31 for the duration of the IE signal. The integrator 31 here thus implements the function f in the programming amplitude formula given above.

After IE has returned to logic 0, the write-enable signal WE goes high signaling the start of the programming portion of the cycle. When WE goes high, switch S₂ closes allowing the capacitor C to discharge in preparation for the next programming cycle. Switch S₄ also closes, and the integration result from integrator 31 is then supplied as a correction signal ΔV to the second input of adder block 32. The correction ΔV is thus added to the constant-amplitude portion of the bias signal V_{B}, whereby the modified signal V_{BL} at the adder output provides the functional programming signal for the cell. This corresponds to the high-amplitude programming portion p of the V_{BL} pulse in FIG. 4. In this way, the programming pulse amplitude is set in dependence on the current cell-state as indicated by the metric T_{M}.

The correction ΔV is stored in integrator block 31. In the next cycle of the iterative programming procedure, the new integrated value is added as a correction to the previously-stored ΔV value to obtain the new correction ΔV for the current cycle. In this way, the amplitude corrections are accumulated, whereby the incremental correction calculated in a given cycle (k+1) is effectively added to the pulse amplitude A(k) for the immediately preceding cycle as in the formula given above.

Successive programming cycles are performed in a similar manner, and the process iterates until controller 5 determines that a preset programming criterion has been met. This can be, for example, that the output of difference block 30 is zero (or sufficiently close to zero, e.g. less than a small threshold value, according to requirements of a given system), signifying that the desired cell-state has been reached. Hence, controller 5 can monitor the output of block 30 for this purpose. As an alternative, or in addition, a limit can be set on the number of programming cycles of the iterative procedure according to operating constraints of the system in question.

The effect of the iterative programming procedure is that the state of cell 10 gradually converges on the desired programmed state as defined by the reference value T_{ref}. This is illustrated by the simulation results of FIG. 7 which shows the measured value of the metric T_{M}, expressed in arbitrary units (a. u.), for ten successive programming pulses in the iterative programming operation. This figure demonstrates how the time metric value quickly converges on the reference value T_{ref}, here 1.25. T_{M}=T_{ref} on the eighth pulse, whereby the target programmed state is achieved in the eighth cycle of the iterative procedure.

It will be seen that the above embodied system exploits cell-state information obtained during the rising slope of a programming pulse to determine the subsequent form of that pulse. Thus, in each programming cycle, the programming operation is adapted to account for current cell-state. By inferring cell-state information from the programming pulse as described, and using that information to program the cell, the system can provide significantly enhanced programming bandwidth. In addition, as described above with reference to FIG. 5, the measurement and programming operation can be performed in an analog manner, avoiding the need for data converters or elaborate digital logic circuitry. The programming system can offer substantial savings in power, latency and complexity of PCM programming.

The time metric measurement technique can also be used to determine cell-state during a read operation of device 1. Use of the time metric to determine cell-state forms the subject of our co-pending and commonly owned U.S. patent application Ser. No. 13/415,012 entitled “Determining Cell-State in Phase-Change Memory”, the content of which is incorporated herein by reference. However, during a read operation a bias voltage having the profile of the measurement portion m described above can be applied to a cell. The time for the resulting cell current to satisfy the predetermined condition, e.g. reach current threshold I_{D} as described above, can then be measured. The resulting time measurement provides a metric for cell-state and can be used by controller 5 to determine the stored level.

In particular, level detection can be performed in controller 5 by comparing the time metric with a plurality of predetermined reference values. The reference values can correspond, for example, to pre-calculated metric values defining the different cell levels, or threshold values defining the boundaries between respective ranges of metric values which are deemed to map to the different cell levels. Comparison of the calculated metric with the reference values in controller 5 thus yields the stored cell-level. The resulting readback data is then output by controller 5 for further read-processing in order to recover the user data as discussed above.

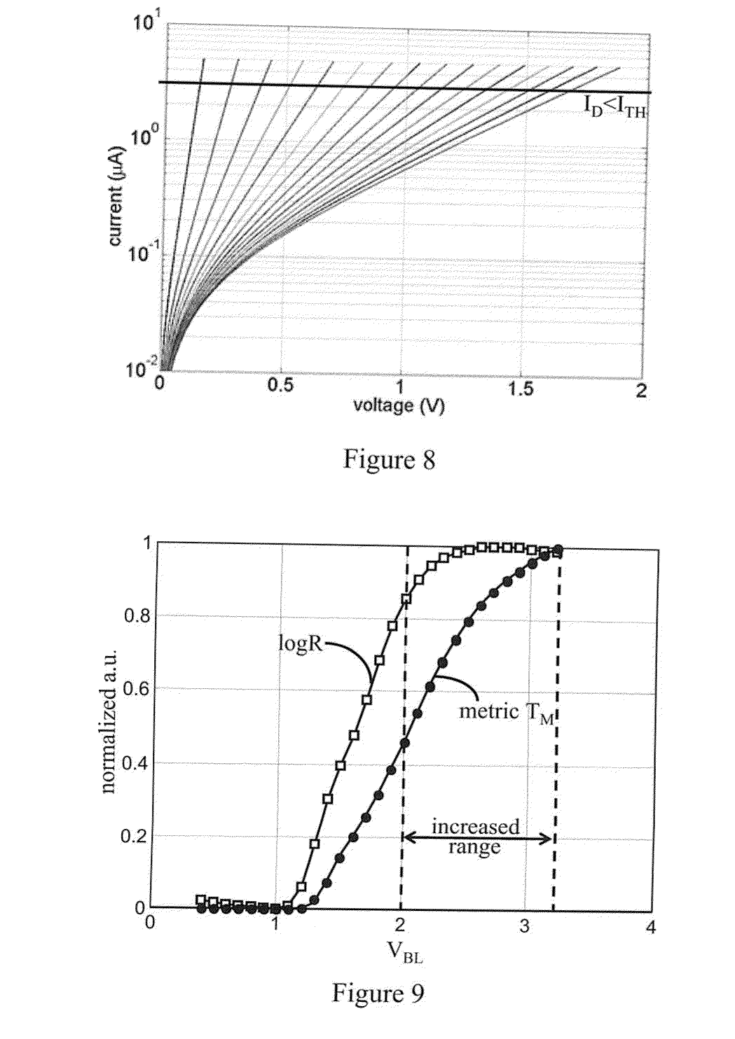

As a metric for cell-state, the metric T_{M} has considerable advantages over the conventional low-field resistance metric. One aspect of the advantages of the metric T_{M} is apparent from FIG. 8. This figure indicates the current threshold I_{D} used in the time measurement operation for the simulated I/V curves for 16-level cells shown in FIG. 1. Since the profile of the measurement portion m of the V_{BL} pulse is linear with time in this embodiment, the voltage scale in FIG. 8 is analogous to time and the voltage at which each curve reaches current threshold I_{D} is a direct analog of the time metric T_{M} measured by timer unit 27. It can be seen that all cell levels are well separated in time at the threshold I_{D}, so even the high-uₐ cell states can be accurately distinguished with the metric T_{M}. Whereas geometric effects cause the resistance metric to saturate at high amorphous thicknesses, the metric T_{M} continues to provide effective level discrimination for high-uₐ states.

The geometric effects do not therefore significantly impact the metric T_{M} and the metric can effectively capture high-uₐ cell states. As a consequence, the usable programming space is significantly enhanced when the metric T_{M} is used to determine cell-state. This is apparent from FIG. 9 which compares average programming curves measured with the resistance metric (log R) and the metric T_{M} normalized to the same effective window. The ordinate axis here indicates normalized average units (a.u.). In the high-field region above V_{BL}=2V, the Log R measurements saturate while the time metric curve continues to display strong linearity and good level discrimination. This provides a substantial increase in the programming range available with the metric T_{M}.

Analysis of the PCM cell using a Poole-Frenkel type conduction model demonstrates further advantages of the metric T_{M}. Assuming that a layer of a-GST is sandwiched between two circular electrodes of radius r, then the current that flows though the GST layer is given by:

$$I = 2 q \frac{π {r}^{2}}{τ} \frac{1}{Δ {z}^{2}} {e}^{\frac{{E}_{c} - {E}_{f}}{kT}} sinh [ \frac{q Δ zV}{2 {kTu}_{a}} ] \qquad ( 1 )$$

where q is the elementary charge, Tₒ is the characteristic attempt to escape time for a trapped electron, Δz is the mean inter-trap distance, k is the Boltzmann constant and T is the temperature. E_{c}−E_{f} is the activation energy. Applying this model to the cell geometry of FIG. 4 using an effective amorphous thickness u_{aeff} and effective radius r_{eff}, the low field resistance can be expressed as:

$$R = \frac{{kTu}_{aeff} {τ}_{0} Δ z {e}^{\frac{{E}_{c} - {E}_{f}}{kT}}}{{q}^{2} π {r}_{eff}^{2}} \qquad ( 2 )$$

In contrast, the time metric T_{M} of the above embodiment can be expressed as:

$${T}_{M} = \frac{2 {kTu}_{aeff}}{q Δ {zk}_{slope}} {sinh}^{- 1} [ \frac{{I}_{D} {τ}_{0} Δ {z}^{2} {e}^{\frac{{E}_{c} - {E}_{f}}{kT}}}{2 q π {r}_{eff}} ] \qquad ( 3 )$$

where kₛₗₒₚₑ is the slope of the ramp profile of the bias voltage measurement portion. It can be seen from equation (2) that the resistance metric is a strong function of the activation energy of the cell. The activation energy is strongly influenced by the defect density and physical attributes like compressive and tensile stress. Drift behaviour commonly observed in the resistance metric, and low frequency fluctuations, are attributed to similar variations in activation energy.

However, it can be seen that these undesirable attributes are not related to the fundamental programmed entity which is the amorphous size and the corresponding effective amorphous thickness. As indicated by equation (3), the metric T_{M} is a strong function of the effective amorphous thickness but is less dependent on the activation energy. Whereas the resistance metric is proportional to the activation energy term in Equation (2), this term only appears in the 1/sin h term in Equation (3) for the metric T_{M}. This indicates a significant reduction in impact of drift and low frequency noise on the metric T_{M}.

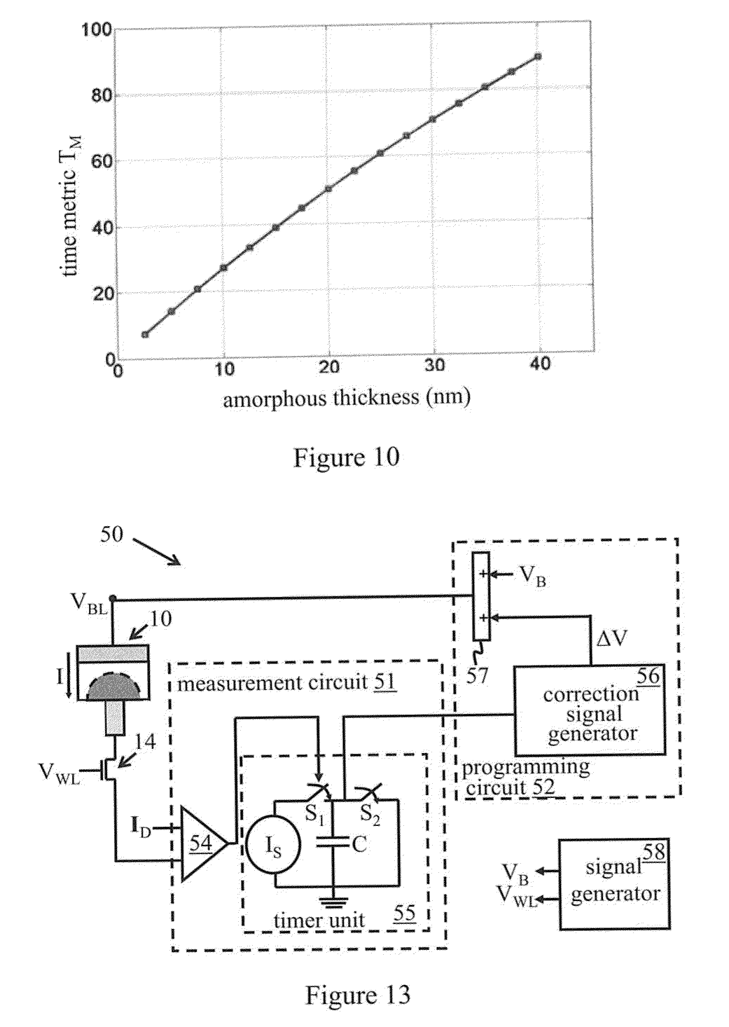

Equation (3) also indicates that the metric T_{M} is a strong function of the effective amorphous thickness but only a weak function of the effective contact radius r_{eff}. This indicates that the time metric should not saturate at high values of amorphous thickness as already discussed above. This is further confirmed by the plot of T_{M} against amorphous thickness obtained from simulation results in FIG. 10. This shows strong linearity of T_{M} with amorphous thickness and good level discrimination across the range.

A still further advantage over the resistance metric is that the metric T_{M} is directly measured and so there is no 1/x compression. Overall, therefore, it will be seen that the metric T_{M} provides an improved metric for amorphous size and hence cell-state.

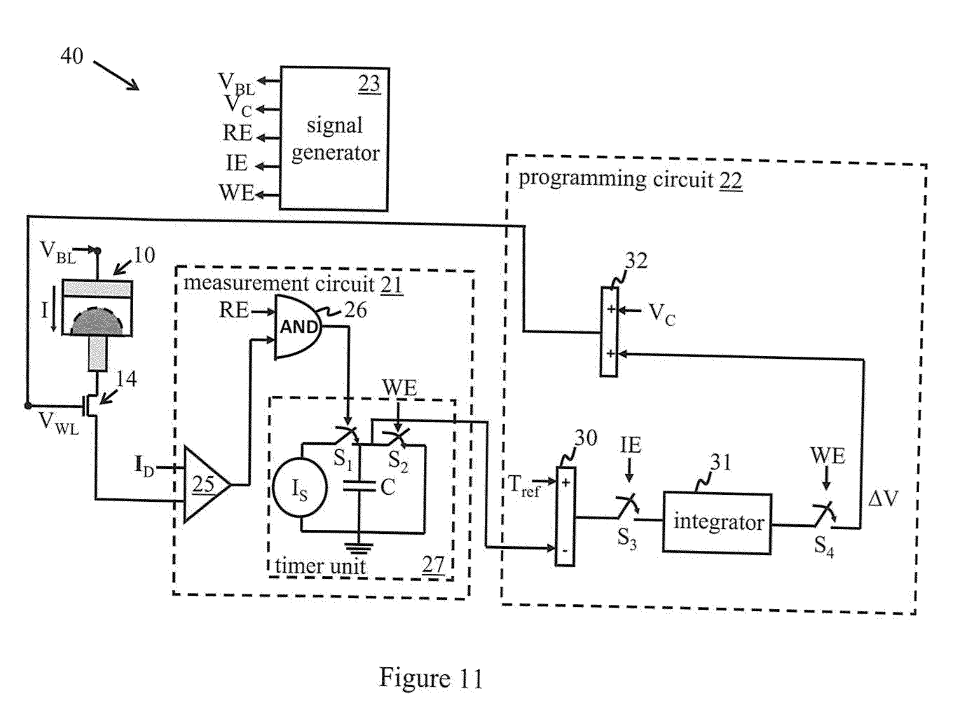

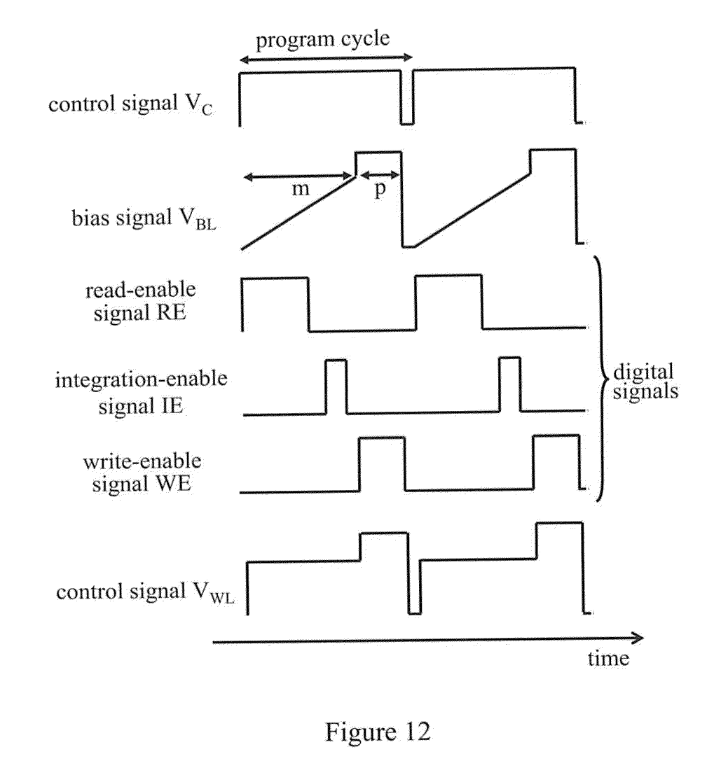

An alternative embodiment for implementing current-mode programming will now be described with reference to FIGS. 11 and 12. FIG. 11 illustrates the current-mode programming apparatus 40. This corresponds generally to apparatus 20 of FIG. 5, with like elements being marked by like reference numerals, and only the key differences will be described here. In this embodiment, the bias voltage signal V_{BL} applied to the bit line of cell 10 is generated by signal generator 23. An analog control signal V_{c}, shown in FIG. 12, is produced by signal generator 23 and supplied to one input of the adder block 32. The other input of adder block 32 receives the correction ΔV as before. The output of adder block 32 is connected to the word line WL, providing the control voltage V_{WL} for transistor 14.

The various control signals are shown in FIG. 12 and operation is substantially as before, but the programming signal is generated here by modifying the control voltage V_{WL}. In particular, during the measurement portion m of the bias voltage signal, V_{WL} corresponds to the control signal V_{c}. During the programming portion p, however, the programming signal is generated by adding the correction ΔV to the control signal V_{c} to change the amplitude of V_{WL}. The resulting control signal V_{WL} is illustrated schematically as the lowest trace in FIG. 12. The amplitude of the programming portion of control signal V_{WL} is thus determined by the metric T_{M} in the manner already described. In this embodiment, however, the transistor 14 acts as a voltage-controlled current source and programming is effected by the resulting current pulses in cell 10.

While an iterative programming system has been described above, single pulse programming can be performed in other embodiments of PCM device 1. An example of single-pulse programming apparatus for use in circuitry 4 of such devices is illustrated in FIG. 13. The apparatus 50 comprises a measurement circuit 51 and a programming circuit 52. Measurement circuit includes a comparator 54 and a timer unit 55 as before. Programming circuit 52 includes correction signal generator 56 and an adder block 57. In this example, the apparatus performs voltage-mode programming and a signal generator 58 produces analog signals V_{WL} and V_{B} as for apparatus 20 of FIG. 5, though in this case for a single cycle only. The bias signal V_{B} forms one input to adder 57 the output of which provides the bias voltage signal V_{BL} at the bit line of cell 10.

In operation, switch S₂ is initially open, the capacitor C is discharged and the bias signal V_{B} is applied as the cell bias voltage V_{BL}. This provides the predetermined measurement portion m of the V_{BL} pulse as described above. The current I flowing through cell 10 during this period is supplied to one input of comparator 54. Comparator 54 compares the current level I with the predetermined current threshold I_{D} described above. While I<I_{D}, the comparator outputs logic 1 and switch S₁ of timer unit 55 is closed. While switch S₁ is closed, the capacitor C is charged by current source I_{S}. As soon as cell current rises so that I≧I_{D}, the comparator outputs logic 0 and switch S₁ opens. The voltage across capacitor C when switch S₁ opens is thus determined by the time taken for the cell current I to reach the current threshold I_{D}. This voltage provides the time metric T_{M} for the programming operation.

The metric T_{M} from measurement circuit 21 is output to the correction signal generator 56 which uses the metric to calculate a correction ΔV to the constant-amplitude portion of the V_{BL} pulse. The correction signal ΔV is supplied to the second input of adder block 57. The correction ΔV is thus added to the constant-amplitude portion of the bias signal V_{B}, whereby the modified signal V_{BL} at the adder output provides the functional programming signal for the cell. In this way, the programming pulse amplitude is set in dependence on the current cell-state as indicated by the metric T_{M}. After programming, a control signal from controller 5 causes switch S₂ to close, allowing capacitor C to discharge, and the operation is complete.

In the single-pulse (SP) system, the programming pulse amplitude is determined as before by the time metric T_{M} obtained from the rising edge of programming pulse, i.e.: A(k)=F(T_{M}(k)). Various options can be envisaged for the function F here which is implemented in correction signal generator 56. For example, the pulse amplitude can depend on the difference between T_{M} and a reference value as in the earlier example. As a particularly simple example which can be appropriate for SP programming, one of a number of predefined pulse amplitudes can be selected for the programming pulse based on the measured value of T_{M}. The function F can be selected as desired based on constraints and requirements of a given system.

By inferring cell-state information from the programming pulse as described, and using that information to program the cell, accuracy can be improved over conventional SP programming. It is expected that the read-verify step required in conventional SP systems can be omitted in SP embodiments of the invention. This offers enhanced programming bandwidth and substantial savings in power, latency and programming complexity.

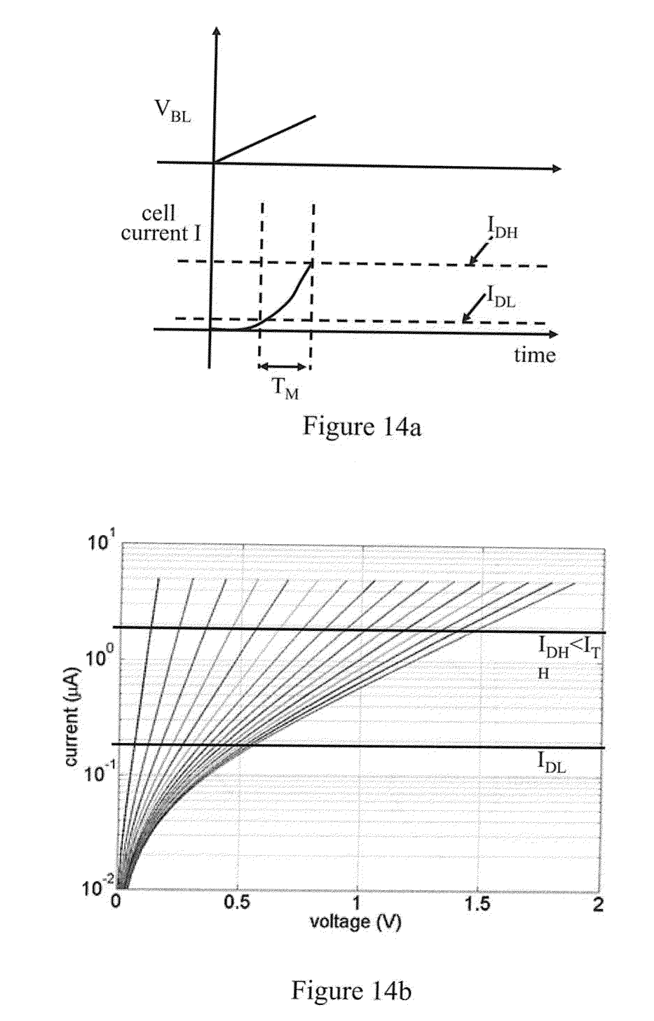

While exemplary embodiments have has been described above, various alternative embodiments can be envisaged. By way of example, some alternative methods for deriving a time-based metric will be described below with reference to FIGS. 14a to 17.

FIGS. 14a and 14b illustrate a first method. FIG. 14a shows the form of the measurement portion of a V_{BL} pulse, together with the corresponding cell current I, and indicates the thresholding technique employed for obtaining the time metric. FIG. 14b is of similar form to FIG. 8 above. Here, the condition to be satisfied by the cell current on making the time measurement is different to that used above. The condition here is that the cell current I changes from a first, lower current level I_{D1} to a second, higher current level I_{D2}. The time for the cell current to increase from the lower to the higher threshold is measured as the metric T_{M}. Analysis based on Equation (3) above indicates that this “time difference metric” should exhibit even greater tolerance to drift and low frequency noise.

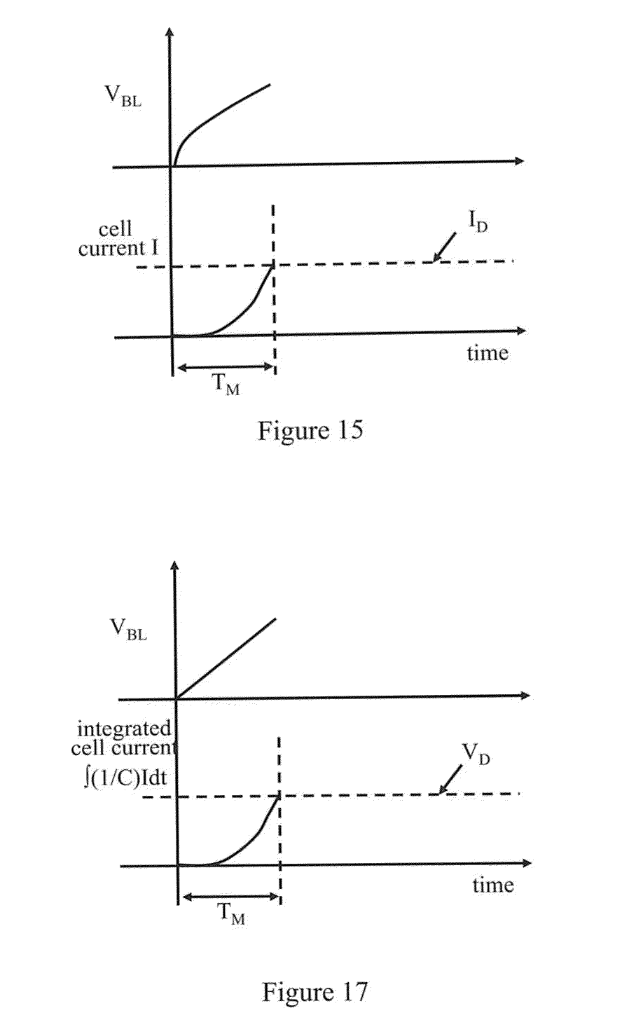

FIG. 15 illustrates a modification to the technique of FIG. 4 in which the profile of the measurement portion of the bias voltage pulse V_{BL} is a non-linear function of time. This can be desirable for a number of reasons. For example, the voltage ramp can be tailored to correct for the hyperbolic sine behavior which causes deviation of the time metric from exponential form at low voltages. Non-linearity can also be used to increase the read bandwidth and/or increase margin of the metric. In general, the time dependence of the measurement portion profile can be altered in various ways to achieve desired effects in different embodiments.

The current thresholds used in the foregoing embodiments are independent of the bias voltage V_{BL}. Alternative embodiments can use current thresholds which are functions of the bias voltage. For example, where the time measurement depends on the current I increasing to a predetermined current level, in the limiting case the predetermined current level can be the threshold switching current. This varies with level, tending to be higher at low levels of amorphous thickness. In this case, the measurement circuit can measure the time at which the cell switches.

Randomness in the switching threshold can limit accuracy in this case however. Therefore, it can be preferred that any current threshold is defined so as ensure measurement before switching. In some embodiments, this can be done by ensuring that the threshold level at any bias voltage level is less than the threshold switching current for all cell states. In other embodiments, however, the threshold can vary with bias voltage level so as to stay under potential switching thresholds attainable at any given voltage level but not necessarily under switching thresholds for all states, in particular those which switch at higher voltage levels. In these embodiments, at any bias voltage level, the threshold current level should be less than the threshold switching current for any cell states having a threshold switching voltage up to that bias voltage level.

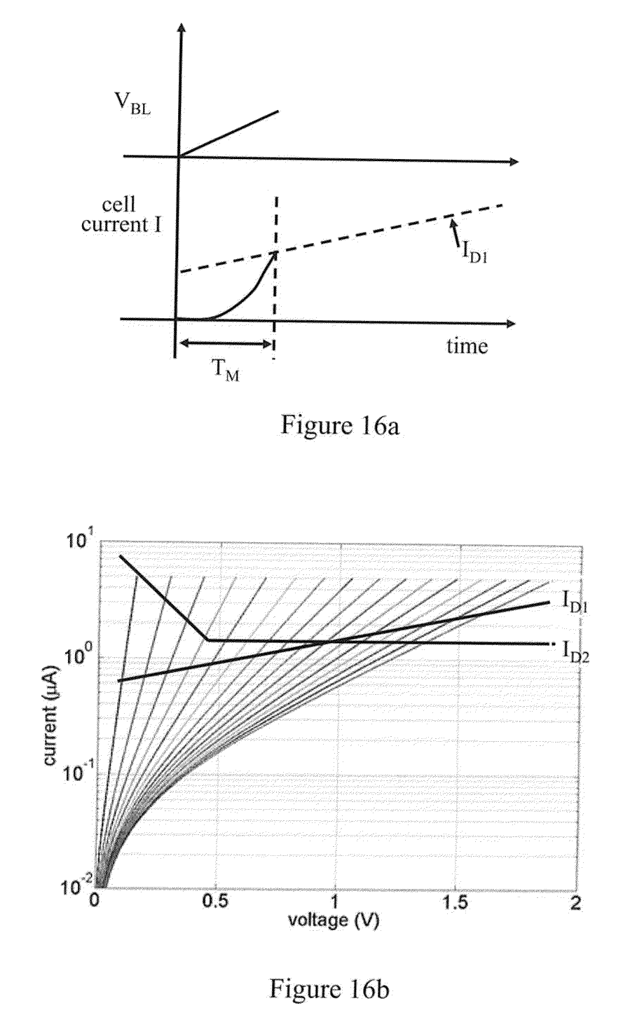

FIGS. 16a and 16b illustrate two examples of current thresholds which are functions of the bias voltage. With threshold I_{D1}, the current threshold is higher at high voltages to increase the signal-to-noise ratio (SNR) in the high-field regime. With threshold I_{D2}, the current threshold is higher at low voltages to increase resolution in the low-field regime. (This threshold illustrates how the threshold level at a given bias voltage level can be higher than the threshold switching current for cell states having threshold switching voltages above that voltage level). At low levels of amorphous thickness it is experimentally observed that the threshold switching current is significantly higher. Hence an increased current threshold I_{D2} at low voltage levels can be employed to enhance the SNR. At higher voltage levels, I_{D2} is still low enough to avoid switching of levels corresponding to high amorphous thickness.

FIG. 17 illustrates an alternative embodiment in which the condition to be satisfied for the time measurement is that a parameter dependent on an integral of the cell current reaches a predetermined level. In this example, the metric T_{M} corresponds to the time taken for the cell current to charge a capacitor (capacitance=C) to a predetermined voltage level V_{D}. Again this threshold level can be set appropriately to avoid threshold switching. Here a constant threshold voltage level V_{D} is used although the threshold can be made dependent on bias voltage if desired. Other parameters dependent on the cell current can also be monitored in other embodiments.

While the time measurement T_{M} is used directly as a cell-state metric according to the embodiment above, if desired the time measurement can be subjected to further processing (e.g. based on additional corrective techniques) to derive the final cell-state metric. In addition, in some embodiments, another parameter indicative of time can be measured, e.g. bias voltage in some embodiments. Also, although it can be preferred that the predetermined profile of the bias voltage measurement portion is a monotonically increasing function as in the embodiments described, alternatives can be envisaged in which the voltage increases generally, though not monotonically, or even decreases with time. For example, an embodiment can be envisaged using a time difference metric similar to FIG. 14a in which the voltage is ramped down from a predetermined (sub-switching threshold) level and the cell current decreases from a higher to a lower threshold.

In a modification to the embodiments described above, the programming signal can be applied immediately after completion of the measurement rather than at a fixed time within the programming cycle. In another modification, when the time measurement is taken the bias voltage level can be frozen for the remainder of the measurement portion. This can avoid traversing the switching threshold before application of the programming signal. This modification can be used to further improve programming accuracy, and can be particularly useful in highly sensitive systems employing large numbers of cell levels.

In the preferred embodiments detailed above, the profile of the measurement portion of the bias signal varies with time in a predetermined manner and the cell-state metric is based on a measurement of the time taken for a condition dependent on cell current to be satisfied. Alternative embodiments can be envisaged in which the profile of the measurement portion does not vary with time in a predetermined manner. For example, the bias voltage level can be varied in a substantially random manner during the measurement portion until the current-dependent condition is determined to be satisfied. As an alternative to such a “random search” procedure, a (possibly arbitrary) bias voltage level can be selected as a starting point, and this level can then be varied according to some predefined algorithm until the current-dependent condition is determined to be satisfied.

A particular example here can be to vary the bias voltage in a feedback manner. The subsequent bias voltage levels can be determined based on cell current. The bias voltage level can thus be caused gradually to converge on the particular level at which the current-dependent condition is satisfied. In any case, in embodiments such as this where the profile of the measurement portion is not predetermined, the measurement used as a metric for cell-state can be a measurement which is (directly or indirectly) indicative of the bias voltage level at which the current-dependent condition is satisfied. Such a metric is superior to the conventional resistance metric for equivalent reasons to those discussed above in connection with the time metric.

While the amplitude of the programming pulse is modified based on cell-state in the systems described, other pulse attributes can be modified in addition or as an alternative to amplitude. For example, the duration of the pulse, or even a trailing edge of the pulse, can be modified in other systems.

Various combinations of the foregoing embodiments can also be envisaged. Suitable modifications to the measurement circuitry to implement the various embodiments will be readily apparent to those skilled in the art.

Various other changes and modifications can be made to the specific embodiments described without departing from the scope of the invention.

1. An apparatus for programming a phase-change memory cell, the apparatus comprising:
a signal generator for generating a bias voltage signal (V_{BL}) to be applied to the cell, a measurement portion (m) of the bias voltage signal having a profile which varies with time;
a measurement circuit for making a measurement (T_{M}) dependent on a predetermined condition, which condition is dependent on cell current during the measurement portion (m) of the bias voltage signal, being satisfied; and
a programming circuit for generating a programming signal in dependence on said measurement (T_{M}) and applying the programming signal to program the cell.

2. A phase-change memory device comprising:
a memory comprising a plurality of phase-change memory cells; and
a read/write apparatus for reading and writing data in the phase-change memory cells, wherein the read/write apparatus includes an apparatus for programming a said memory cell, the apparatus comprising:
a signal generator for generating a bias voltage signal (V_{BL}) to be applied to the cell, a measurement portion (m) of the bias voltage signal having a profile which varies with time;
a measurement circuit for making a measurement (T_{M}) dependent on a predetermined condition, which condition is dependent on cell current during the measurement portion (m) of the bias voltage signal, being satisfied; and
a programming circuit for generating a programming signal in dependence on said measurement (T_{M}) and applying the programming signal to program the cell.

3. The device according to claim 2, wherein said phase-change memory cells are multilevel memory cells.
